(19) United States
(12) Patent Application Publication
(10) Pub. No.: US 2008/0061848 A1
(43) Pub. Date: Mar. 13, 2008

(54) Output driver circuit having a clamped mode and an operating mode

(75) Inventors: David William Howard, Cambridge (GB); David Walter Flynn, Cambridge (GB)

Correspondence Address: NIXON & VANDERHYE, PC, 901 NORTH GLEBE ROAD, 11TH FLOOR, ARLINGTON, VA, 22203, US

(73) Assignee: ARM Limited, Cambridge (GB)

(21) Appl. No.: 11/517,564

(22) Filed: Sep. 8, 2006

(51) Int. Cl. H03K 3/00

(52) U.S. Cl. 327/112

(57) ABSTRACT

An output driver circuit 18 is provided having an operating mode in which the output signal has a variable level dependent upon an input signal and a clamping mode in which the output signal is clamped to a fixed level. The output driver circuit includes a control circuit 20 and an output buffer 22. The output buffer is formed of high strength, high current transistors 24, 26 which also tend to suffer high leakage. In the clamping mode, the power supply to the output buffer 22 is isolated, but the control circuit 20 serves to supply a control signal on line 36 to at least one transistor 26 within the output buffer 22 which is controlled to remain conductive and accordingly serve as a clamping transistor which clamps the output from the output buffer 22 to a fixed level.

### BACKGROUND OF THE INVENTION

1. Field of the Invention

This invention relates to the field of driver circuits. More particularly, this invention relates to an output driver circuit having a clamped mode in which an output signal from the output driver circuit is clamped to a fixed level and an operating mode in which the output signal has a variable level dependent upon an input signal to the output driver circuit.

2. Description of the Prior Art

An important problem within integrated circuits is to reduce the power consumption of those integrated circuits. One known way of achieving this is to provide blocks of circuits within an integrated circuit which can be selectively powered down when they are not required. However, a problem with this approach is that the outputs from powered down blocks which are supplied to other blocks tend to float to non-logic levels that decay slowly with leakage. This is undesirable as it can produce unwanted and unexpected consequences in the remainder of the circuit.

One way of addressing this problem of floating output signals is by adding a clamp or isolation cell that remains powered, or to add some form of pull-up or pull-down structure to clamp the output to a safe level (whilst avoiding a drive clash). Whilst such an approach will address the floating output signal level problem, it can introduce its own problems.

It is common that the interface signals between blocks are on a critical path within the circuit as a whole and therefore when the block is not powered down the interface signal needs a significant drive strength (or incur re-buffering delays). The leakage of such “always-on” strong buffers when clamped compromises the leakage mitigation for the block which has been powered down (especially where there are many outputs from the powered down block.

FIG. 1 of the accompanying drawings schematically illustrates a portion of an integrated circuit (although this could be a general circuit) including a power-gated subsystem 2 and a permanently powered subsystem 4 with protected inputs. The power-gated subsystem 2 generates an output signal which is supplied as an input to the permanently-powered subsystem 4. A power clamp 6 is provided between the power-gated subsystem 2 and the permanently-powered subsystem 4 and serves to hold the input signal to the permanently-powered subsystem 4 at a fixed level in response to a “CLAMPLO” signal when the power-gated subsystem 2 is powered down.

FIG. 2 schematically illustrates a typical implementation of the power clamp circuit 6. This is formed as a NAND-2 gate 8 followed by a more powerful output inverter buffer 10 (denoted with bold lines). The output inverter buffer 10 is formed with larger and faster transistors than is the norm in order to drive what may be a critical path signal. However, the use of such large and fast transistors also brings with it increased leakage associated with those larger and faster transistors.

FIG. 3 schematically illustrates at a transistor level the circuit of FIG. 2. It will be seen that the output inverter buffer 10 is formed of a transistor pair 14, 16 denoted with bold lines as being a high current output transistor pair, which adds to the leakage in an undesirable way. A P-type transistor 12 is controlled by the clamping signal and is conductive when clamping is active to switch off transistor 14 and switch on transistor 16 and so clamp the output signal from the output inverter buffer 10 to a low level. However, leakage through the transistor 14 continues in an undesirable fashion since the output inverter buffer 10 remains powered from the VDD line.

### SUMMARY OF THE INVENTION

Viewed from one aspect the present invention provides an output driver circuit having a clamped mode in which an output signal from said output driver circuit is clamped to a fixed level and an operating mode in which said output signal has a variable level dependent upon an input signal to said output driver circuit, said output driver circuit comprising:

a control circuit responsive to a clamping control signal to control whether said output driver circuit is in said clamping mode or in said operating mode;

an output buffer having an output for outputting said output signal, pullup transistor having a first gate input and a pulldown transistor having a second gate input; wherein
(i) in said operating mode, said control circuit is connected to a control circuit power supply, said output buffer is connected to a buffer circuit power supply and said control circuit supplies one or more signals dependent upon said input signal to said first gate input and said second gate input to control said output buffer including said pullup transistor and said pulldown transistor so that said output buffer generates said output signal; and
(ii) in said clamping mode, said control circuit is connected to said control circuit power supply, said output buffer is not connected to said buffer circuit power supply, and said control circuit supplies a control signal to at least one of said first gate input and said second gate input to render one of said pullup transistor and said pulldown transistor conductive and so clamp said output to said fixed level.

The present technique operates the high-leakage output driver stage from a power-gated “virtual” supply, whilst ensuring that the correct gate voltage is driven to the output driver transistor that needs to become the clamping transistor. This reduces leakage through the output driver stage (since it is no longer connected to a power supply), whilst ensuring that the output from the driver is properly clamped.

In one form of output driver circuit in accordance with the present technique separate power supply rails are provided for the control circuit and the buffer circuit. In an alternative form of embodiment a common power supply rail is provided with the buffer circuit power supply including an isolation gate serving to selectively couple the buffer circuit to the common power supply rail. The isolation gate effectively provides the virtual power supply for the buffer circuit.

The buffer has the job of providing a high strength output signal and can have a variety of different forms. In preferred embodiments the output buffer comprises two buffer transistors with a common gate signal forming an inverter. Other embodiments may have separately provided gate signals which can be timed to ensure both transistors are not turned on at the same time causing a high current transient.

Whilst the present technique could be used to advantage with transistors of equal strength throughout, it is particularly useful when the at least one pullup transistor and pulldown transistor have a greater drive strength and greater leakage current than the transistors forming the control circuit.

The control circuit can be formed in a variety of different ways to provide the signals discussed above for controlling the output buffer. An efficient way of forming the control circuit which uses advantageously few transistors is one in which said control circuit comprises:

a NAND gate having as inputs said input signal and said clamping control signal and as an output said signal dependent upon said input signal; and

a clamping control transistor controlled by said clamping control signal to generate said control signal to said gate input.

In embodiments in which the buffer transistor may be isolated from the voltage to which it is intended to clamp, it is advantageous that the control circuit comprises a further clamping control transistor controlled by the clamping control signal to be conductive and to discharge the output signal to the fixed level.

Whilst it will be appreciated that the output driver circuit of the present technique could be implemented in a variety of different forms, such as by discrete components, the technique is particularly well suited for use within integrated circuits, and in particular may be formed as a standard cell for an integrated circuit for ready inclusion within a normal design flow.

Particularly efficient preferred implementations are ones in which the pulldown transistor is an N-type transistor, the pullup transistor is a P-type transistor the clamping control signal is active low and the control signal is active high.

Viewed from another aspect the present invention provides a method of controlling an output driver circuit having a clamped mode in which an output signal from said output driver circuit is clamped to a fixed level and an operating mode in which said output signal has a variable level dependent upon an input signal to said output driver circuit, said method comprising the steps of:

using a control circuit responsive to a clamping control signal to control whether said output driver circuit is in said clamping mode or in said operating mode;

in said operating mode using an output buffer having a pullup transistor with a first gate input and a pulldown transistor with a second gate input to generate said output signal at an output of said output buffer; wherein
(i) in said operating mode, said control circuit is connected to a control circuit power supply, said output buffer is connected to a buffer circuit power supply and said control circuit supplies one or more signals dependent upon said input signal to said first gate input and said second gate input to control said output buffer including said buffer transistor so that said output buffer generates said output signal; and
(ii) in said clamping mode, said control circuit is connected to said control circuit power supply, said output buffer is not connected to said buffer circuit power supply, and said control circuit supplies a control signal to at least one of said first gate input and said second gate input to render one of said pullup transistor and said pulldown transistor conductive and so clamp said output to said fixed level.

The above, and other objects, features and advantages of this invention will be apparent from the following detailed description of illustrative embodiments which is to be read in connection with the accompanying drawings.

### BRIEF DESCRIPTION OF THE DRAWINGS

FIG. 1 schematically illustrates a circuit including a power-gated subsystem and a permanently-powered subsystem with a clamp circuit therebetween;

FIG. 2 schematically illustrates at a logic gate level one example form of the clamp circuit of FIG. 2;

FIG. 3 schematically illustrates at a transistor level one example form of the clamping circuit of FIG. 2;

FIG. 4 illustrates at a transistor level an output driver circuit in accordance with a first example embodiment of the present technique; and

FIG. 5 schematically illustrates at a transistor level an output driver circuit in accordance with a second example embodiment of the present technique.

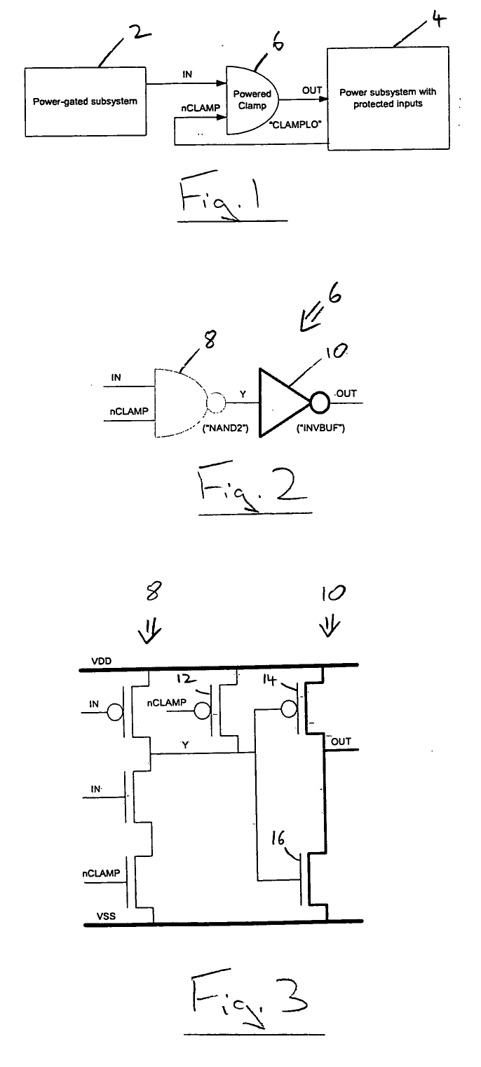

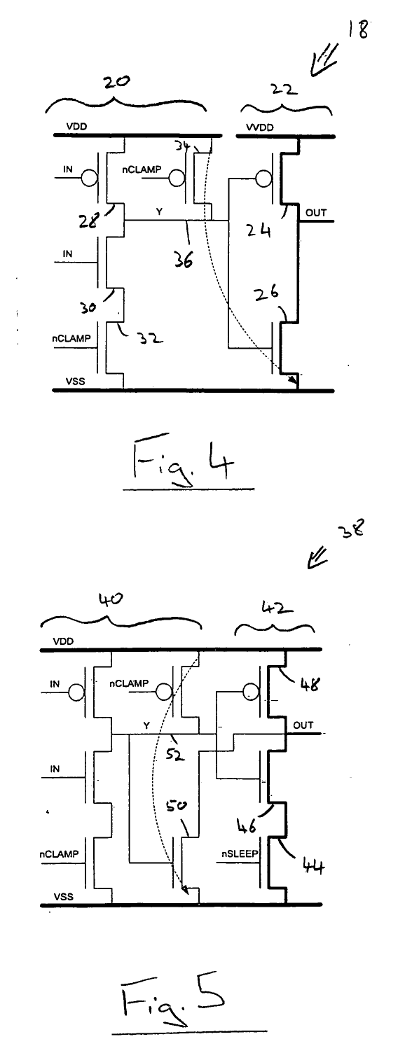

### DESCRIPTION OF THE PREFERRED EMBODIMENTS

FIG. 4 illustrates an output driver circuit 18, which typically may form a standard cell to be included within an integrated circuit, such as a system-on-chip integrated circuit. This output driver circuit 18 is provided between blocks of circuits where one of the blocks is to be selectively powered down. It is desired to control an output generated by the powered down block and supplied as an input to a block which remains powered at a fixed level so as to avoid undesired and unpredictable behaviour within the active circuits to which the signal is supplied. The output driver circuit 18 is formed of a control circuit 20 and an output buffer 22. The output buffer 22 is in the form of two buffer transistors 24, 26 forming an inverter (a pullup transistor 24 and a pulldown transistor 26. These buffer transistors 24, 26 are high drive strength (high drive current) transistors chosen to be fast and powerful and accordingly typically having relatively high leakage currents. Such transistors 24, 26 are desirable for use with signals which are on a critical path. It will be appreciated that a variety of output driver circuit 18 designs could be provided with respective differing strengths of transistors 24, 26 used for the output buffer 22 to suit the particular requirements of the signal being buffered (e.g. there would be no need to use high strength transistors 24, 26 when the circuit concerned was not on a critical path and would have no performance limiting impact should weaker and lower leakage transistors be used.

The control circuit 20 includes a NAND-2 gate and is formed of four transistors 28, 30, 32, 34. The transistors 32 and 34 are controlled by an active low nCLAMP signal which signals that the output driver circuit 18 should be placed into its clamping mode. In this clamping mode the transistors 28 and 30 are isolated from the VSS line by the transistor 32 and the transistor 34 is switched on thereby generating a control signal on line 36 which is high and is supplied to the input gates (respectively a first gate input and a second gate input) of the transistors 24, 26 of the output buffer 22. This control signal is active high in that it switches on the transistor 26 and switches off the transistor 24. The virtual power supply to the output buffer on the signal line VVDD can then be powered down. The control signal on line 36 will remain high and accordingly the transistor 26 will remain conductive and the output of the output buffer 22 clamped low even-though the buffer power supply on the VVDD line is not connected.

In the operating mode, the clamping signal nCLAMP is high such that transistor 32 is switched on and transistor 34 is switched off. In this operating mode, the transistors 28 and 30 serve to supply a signal on line 36 to the gate of the transistors 24 and 26 of the output buffer 22 which is dependent upon the input signal IN. In this operating mode, the output driver circuit 18 serves as a normal buffer. The transistors 28 and 30 serve to invert the input signal and this is inverted again by the transistors 24 and 26 such that a non-inverted buffered output is produced. The dotted line in FIG. 4 shows the control path in the clamping mode by which the transistor 26 is held conductive and so reliably serves as a clamping transistor to clamp the output of the output driver circuit low.

FIG. 5 schematically illustrates another example embodiment. In this embodiment, the output driver circuit 38 is composed of a control circuit 40 and an output buffer 42. A common power supply rail VDD is coupled to both the control circuit 40 and the output buffer 42. An isolation gate 44 responsive to a sleep signal nSLEEP (which can also power down the power-gated subsystem 2) is disposed between an N-type transistor 46 of the output buffer 42 and the ground VSS (or virtual ground) line. A P-type transistor 48 completes the output buffer 42. Each of the transistors 44, 46 and 48 is a high strength, high current transistor suitable for use within an output driver circuit carrying a critical path related signal.

The control circuit 40 is similar to that illustrated in FIG. 4 with the addition of controlling a further clamping control transistor 50 within the output buffer 42, which serves as a pulldown transistor. The control signal on line 52, which is generated when in the clamping mode and serves to hold the transistor 46 conductive, also serves to hold the further clamping control transistor 50 conductive. The further clamping control transistor 50 is coupled to the output signal from the output buffer 42 and discharges this to VSS even though the isolation gate 44 may have isolated the output buffer 42 from the virtual ground level VSS. The dotted line in FIG. 5 shows the control path which serves to ensure that the output from the output driver circuit 38 is clamped low.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope and spirit of the invention as defined by the appended claims.

We claim:

1. An output driver circuit having a clamped mode in which an output signal from said output driver circuit is clamped to a fixed level and an operating mode in which said output signal has a variable level dependent upon an input signal to said output driver circuit, said output driver circuit comprising:
a control circuit responsive to a clamping control signal to control whether said output driver circuit is in said clamping mode or in said operating mode;
an output buffer having an output for outputting said output signal, pullup transistor having a first gate input and a pulldown transistor having a second gate input; wherein
(i) in said operating mode, said control circuit is connected to a control circuit power supply, said output buffer is connected to a buffer circuit power supply and said control circuit supplies one or more signals dependent upon said input signal to said first gate input and said second gate input to control said output buffer including said pullup transistor and said pulldown transistor so that said output buffer-generates said output signal; and
(ii) in said clamping mode, said control circuit is connected to said control circuit power supply, said output buffer is not connected to said buffer circuit power supply, and said control circuit supplies a control signal to at least one of said first gate input and said second gate input to render one of said pullup transistor and said pulldown transistor conductive and so clamp said output to said fixed level.

2. An output driver circuit as claimed in claim 1, wherein said control circuit power supply includes a control circuit power supply rail and said buffer circuit power supply includes a buffer circuit power supply rail, said control circuit power supply rail being separate from buffer circuit power supply rail.

3. An output driver circuit as claimed in claim 1, wherein said control circuit power supply includes a common power supply rail and said buffer circuit power supply includes an isolation gate selectively coupling said buffer circuit to said common power supply rail.

4. An output driver circuit as claimed in claim 1, wherein said first gate input and said second gate input are tied together and said pullup transistor and said pulldown transisitor form an inverter.

5. An output driver circuit as claimed in claim 1, wherein said pullup transistor and said pulldown transistor have a greater drive strength and a greater leakage current than transistors forming said control circuit.

6. An output driver circuit as claimed in claim 1, wherein said control circuit comprises:
a NAND gate having as inputs said input signal and said clamping control signal and as an output said signal dependent upon said input signal; and
a clamping control transistor controlled by said clamping control signal to generate said control signal to said gate input.

7. An output driver circuit as claimed in claim 6, wherein said control circuit comprises a further clamping control transistor controlled by said clamping control signal to be conductive and to discharge said output signal to said fixed level.

8. An output driver circuit as claimed in claim 1, wherein said output driver circuit is formed as a standard cell for an integrated circuit.

9. An output driver circuit as claimed in claim 1, wherein said pulldown buffer transistor is an N-type transistor and said pullup transistor is a P-type transistor.

10. An output driver circuit as claimed in claim 1, wherein said clamping control signal is active low and said control signal is active high.

11. A method of controlling an output driver circuit having a clamped mode in which an output signal from said output driver circuit is clamped to a fixed level and an operating mode in which said output signal has a variable level dependent upon an input signal to said output driver circuit, said method comprising the steps of:
using a control circuit responsive to a clamping control signal to control whether said output driver circuit is in said clamping mode or in said operating mode;
in said operating mode using an output buffer having a pullup transistor with a first gate input and a pulldown transistor with a second gate input to generate said output signal at an output of said output buffer; wherein
(i) in said operating mode, said control circuit is connected to a control circuit power supply, said output buffer is connected to a buffer circuit power supply and said control circuit supplies one or more signals dependent upon said input signal to said first gate input and said second gate input to control said output buffer including said buffer transistor so that said output buffer generates said output signal; and
(ii) in said clamping mode, said control circuit is connected to said control-circuit power supply, said output buffer is not connected to said buffer circuit power supply, and said control-circuit supplies a control signal to at least one of said first gate input and said second gate input to render one of said pullup transistor and said pulldown transistor conductive and so clamp said output to said fixed level.
